(19) United States
(12) Patent Application Publication
(10) Pub. No.: US 2006/0046433 A1
(43) Pub. Date: Mar. 2, 2006

(54) Thinning semiconductor wafers

(76) Inventors: Terry L. Sterrett, Cave Creek, AZ (US); Leonel R. Arana, Phoenix, AZ (US); Devendra Natekar, Chandler, AZ (US)

Correspondence Address: TROP PRUNER & HU, PC, 8554 KATY FREEWAY, SUITE 100, HOUSTON, TX, 77024, US

(21) Appl. No.: 10/925,775

(22) Filed: Aug. 25, 2004

(51) Int. Cl. H01L 21/463

(52) U.S. Cl. 438/459; 438/613; 269/55

(57) ABSTRACT

Wafer thinning may be accomplished by grinding while the wafer is held in the fixture. The fixture may have a series of protrusions that form an interference fit with surface features extending outwardly from the non-thinned surface of the wafer to be thinned. In some embodiments, a releasable adhesive may be utilized to augment the interference effect. Also, in some embodiments, openings in a shape memory material may be utilized that, upon heating, more firmly engage the bumps on the wafer to be thinned.

### BACKGROUND

This invention relates generally to thinning semiconductor wafers.

Thinning semiconductor wafers may be desirable, for example, because thinner wafers may have reduced thermal resistance and increased reliability. Thinning the wafer may reduce the die stress from thermal effects, thereby increasing reliability. The thickness of the wafer may also affect the package size adversely. In some cases, the thickness of the wafer may adversely affect performance. Thus, for a variety of reasons it is desirable to thin semiconductor wafers.

As wafers are made thinner and thinner still, the severity of wafer damage may increase dramatically. At thicknesses below 5 mils, wafers are prone to cracking, surface burnishing, and surface irregularities. Bumped wafers may have additional problems related to surface pitting in areas between bumps. Especially with very thin wafers, the wafers are prone to damage during removal from the thinning fixture.

Thus, there is a need for better ways to thin semiconductor wafers.

### BRIEF DESCRIPTION OF THE DRAWINGS

FIG. 1 is a cross-sectional view of one embodiment of the present invention at an early stage.

FIG. 2 is a cross-sectional view corresponding to FIG. 1 at a subsequent stage in accordance with one embodiment of the present invention;

FIG. 3 is a cross-sectional view corresponding to FIG. 2 at a later stage in accordance with one embodiment of the present invention;

FIG. 4 is a cross-sectional view corresponding to FIG. 3 after subsequent operations in accordance with one embodiment of the present invention;

FIG. 5 is a cross-sectional view of the thinned wafer in accordance with one embodiment of the present invention;

FIG. 6 is a cross-sectional view of a wafer thinning process at an early stage in accordance with another embodiment of the present invention;

FIG. 7 is a cross-sectional view corresponding to FIG. 6 at a later stage in accordance with one embodiment of the present invention;

FIG. 8 is a cross-sectional view of still another embodiment of the present invention at an early stage;

FIG. 9 is a cross-sectional view of the embodiment shown in FIG. 8 at a subsequent stage in accordance with one embodiment of the present invention; and

FIG. 10 is a cross-sectional view corresponding to FIG. 9 after further processing in accordance with one embodiment of the present invention.

### DETAILED DESCRIPTION

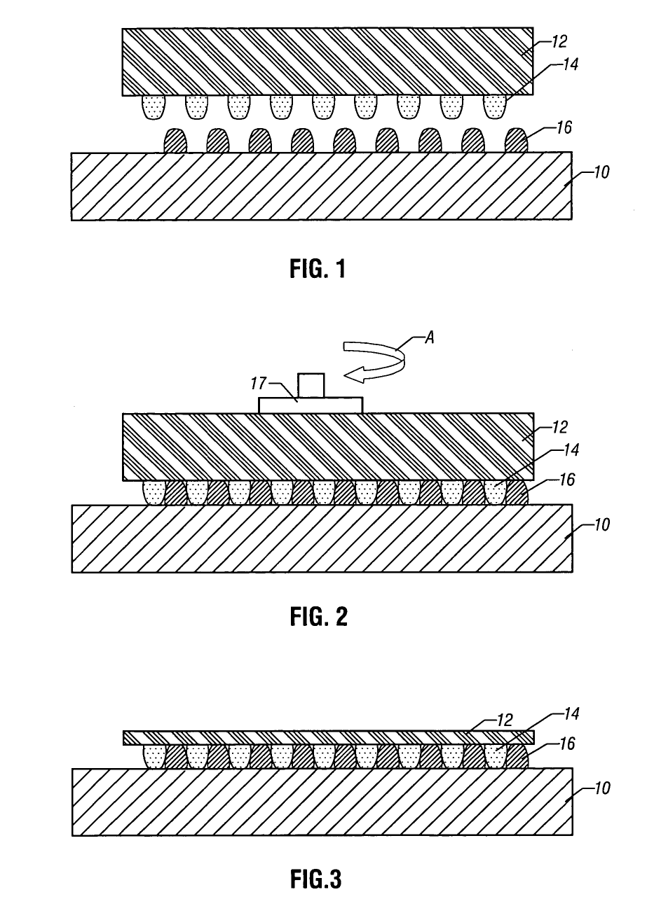

Referring to FIG. 1, a wafer 12 to be thinned may have a plurality of surface features 14. In one embodiment, the features 14 may be surface mount bumps or solder balls. Solder balls may generally be elongated prior to softening. The features 14 may be present to facilitate electrical connections or they may be applied solely to facilitate thinning.

A fixture 10 may hold the wafer 12 during processing. It may have a plurality of protrusions 16 that, in one embodiment, may also be solder balls or surface mount features. In another embodiment, the protrusions may be integral with the fixture 10.

As shown in FIG. 2, the distance between the protrusions 16 and the features 14 is such that the two features may effectively lock in an interference fit, as shown in FIG. 2, when the two wafers 12 and fixture 10 abut in the vertical direction. As a result, the wafer 12 may be held firmly if a two dimensional array or pattern of relatively evenly spaced features 14 and protrusions 16 are provided. Once the wafer 12 is fixed, it can be subjected to rotary grinding using a conventional wafer grinding tool 17.

Where the protrusions 16 are integral with the fixture 10, the fixture 10 may be formed, for example, of etched silicon, borosilicate glass, or alumina. The protrusions 16 may have dimensions similar to the features 14 on the wafer 12 with corresponding spacing and pitch. In some embodiments, the features 14 may be offset such that the protrusions 16 lie in interstitial areas between features 14. As a result of the interference fit, the wafer 12 may be firmly secured while it is subjected to rotary grinding motion indicated by the arrow A in FIG. 2.

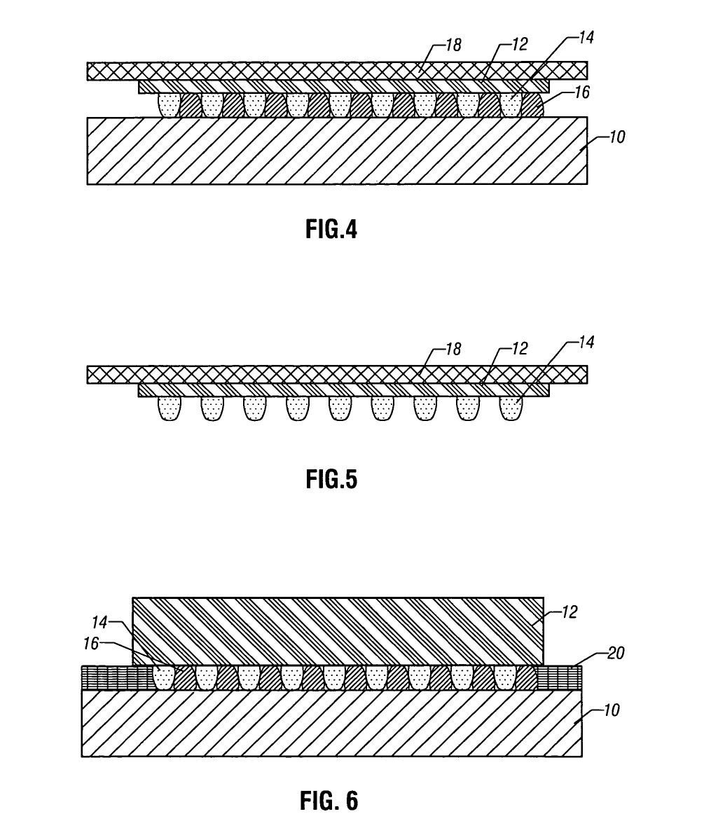

Eventually, the wafer 12 may be thinned as indicated in FIG. 3. Thereafter, as indicated in FIG. 4, a dicing tape 18 may be applied to the thinned wafer 12. As a result, the thinned wafer 12 may be physically removed from the fixture 10 by applying a force to the tape 18 which is releasably, adhesively secured to the wafer 12. In some embodiments, the features 14 may be removed by the application of heat.

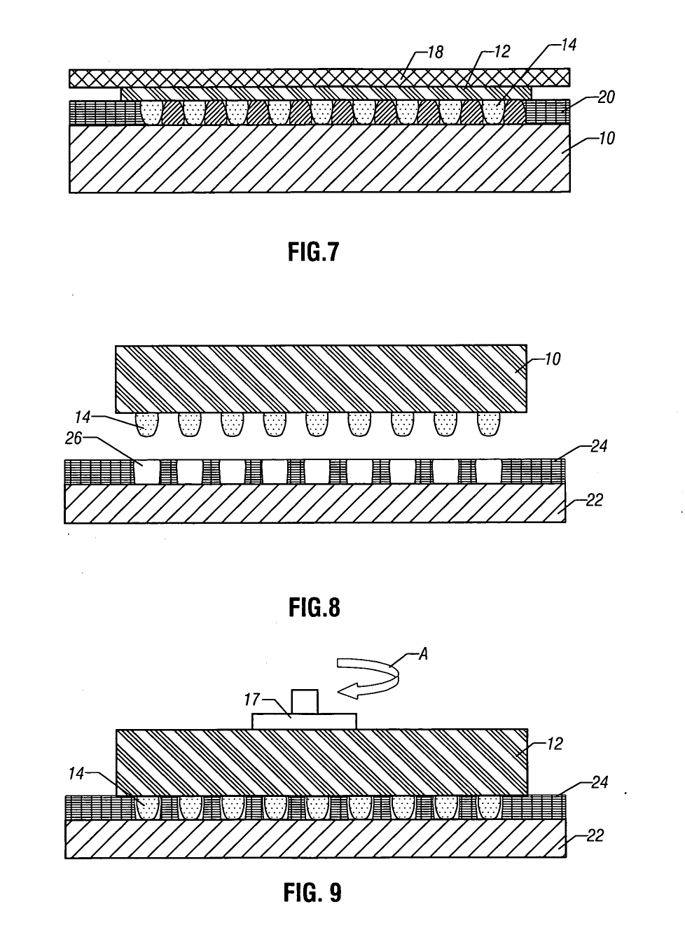

In accordance with another embodiment of the present invention, shown in FIGS. 6 and 7, the techniques described in connection with FIGS. 1-5 may be utilized with the addition of an adhesive material 20. The adhesive material 20 may be a thermoplastic resin which provides additional, releasable adhesion between the fixture 10 and the wafer 12.

For example, the adhesive 20 may be a thermoplastic resin initially heated to its melting point. Once it reaches its melting point, it can be engaged by the wafer 12 and, particularly, by the features 14. Once the two elements are engaged, as shown in FIG. 6, the adhesive 20 may be allowed to cool to at least 20° C. below its melting temperature. In one embodiment of the present invention, the adhesive 20 may be GenTak 330, available from General Chemical Corporation, Hollister, Calif.

Referring to FIG. 7, after the wafer 12 has been thinned, dicing tape 18 may be again applied to remove the wafer 12 from the fixture 10. The removal process may be facilitated by heating the adhesive 20 before attempting to remove the wafer 12 and, further, in some embodiments, by immersing the entire structure in a suitable solvent that softens or attacks the adhesive 20. A suitable solvent may include the Gensolve 335, also available from General Chemical.

Referring to FIG. 8, in accordance with another embodiment of the present invention, the fixture 22 may be covered by a film 24 with openings 26 formed therein. The regions between openings 26 act as protrusions 16. In one embodiment of the present invention, the film 24 may be a shape memory alloy film such as superelastic Nitinol or a shape memory polymer such as segmented polyurethane elastomers comprised of aromatic diisocyanates and poly(caprolactone). The diisocyanates may be methylene diiscyante in one embodiment of the present invention. The material used for the film 24 remembers a given shape and returns to that shape under the appropriate temperature conditions.

The openings 26 may correspond generally to the horizontal dimensions of the features 14. Initially, the openings 26 may be slightly larger than the features 14 in order to allow a feature 14 to be inserted into an opening 26. Thus, as shown in FIG. 9, the features 14 can be inserted into the openings 26. The film 24 is formulated such that its memorized opening 26 size is slightly smaller than the corresponding dimensions of the features 14 to facilitate capturing the wafer 12 when the film 24 returns to its memorized configuration.

In some embodiments, the film 24 may be made of a sheet of Nitinol metal or from woven Nitinol structure with the openings in the woven pattern for forming the openings 26 for capturing the features 14.

The shape memory alloys may be alloys that undergo a martensitic phase transformation that yields a thermoelastic martensite phase exhibiting high elongation characteristics. This phase typically appears as a herringbone structure formed from an assembly of alternately sheared platelets. As the temperature increases, the martensite phase transforms to the austenite, decreasing the starting dimensions of the film 24 openings 26.

This transformation may not occur at a single temperature, but, instead, may occur over a range of temperatures that varies with each alloy system. Most of the transformation may occur over a relatively narrow temperature range, although the beginning and ending of the transformation, during heating or cooling, actually extends over a much larger temperature range. The transformation may also exhibit hysteresis in that the transformations on heating and on cooling do not overlap.

Referring to FIG. 9, when the grinding of the wafer 12 is implemented using the grinder 17, the wafer 12 heats up, heating up the film 24. As the film 24 heats up, it tends to shrink down, grabbing the features 14. More particularly, the film 24 is transformed to its martensitic phase.

In one embodiment of the present invention, Nitinol shape memory alloy having an austenitic phase at room temperature and a martensitic phase transformation in the range of 40° C. to 100° C. may be utilized. The diameter of the openings 26, in the film 24, may be from about 1 to about 8 percent greater than the feature 14 diameter, to allow easy engagement and self-alignment of the features 14 and the fixture 22. Upon wafer thinning, the heat generated due to the frictional forces causes heating to temperatures greater than 40° C. As a result, the film 24 transforms to the martensitic phase, in which its openings 26 are smaller, reducing the diameter of the openings 26 and engaging the features 14.

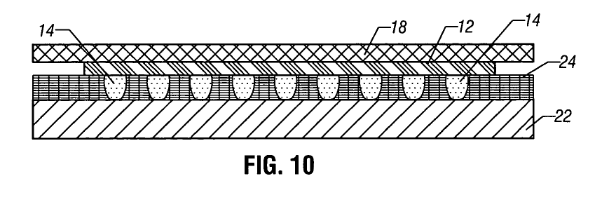

In some embodiments, the fixture 22 may also be equipped with a heater that heats the film 24 in order to positively engage the features 14. After thinning, the structure may be cooled to room temperature, causing the openings 26 to increase in diameter, thereby releasing the wafer 12 that has been thinned, as shown in FIG. 10. The wafer may again be removed by attaching a tape 18 and pulling the wafer 12 from the fixture 22.

Thus, in some embodiments of the present invention, wafers to be thinned may be more effectively held. This may reduce wafer damage during thinning operations such as when wafers are thinned to 5 mils or less.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A method comprising:
forming a plurality of protrusions on a wafer and engaging said protrusions in a fixture; and
exposing the wafer to a grinding operation to thin said wafer.

2. The method of claim 1 including forming protrusions on said wafer in the form of bumps.

3. The method of claim 2 including forming protrusions in the form of solder bumps.

4. The method of claim 3 including forming a two dimensional array of relatively evenly spaced solder bumps.

5. The method of claim 1 including using a releasable adhesive to secure said wafer to said fixture.

6. The method of claim 5 including softening said adhesive to secure said wafer to said fixture and softening said adhesive to remove said wafer from said fixture.

7. The method of claim 1 including using a shape memory material to secure said protrusions to said fixture.

8. The method of claim 7 including providing a shape memory material and forming a plurality of protrusions in said shape memory material.

9. The method of claim 8 including using a material which has an austenitic phase in which the openings are larger than the martensitic phase.

10. The method of claim 9 including enabling said film to transform to its martensitic phase upon heating.

11. The method of claim 10 including enabling said material to transform to its martensitic phase in response to heating caused by grinding said wafer to thin said wafer.

12. A fixture comprising:
a support surface; and
a two dimensional array of evenly spaced protrusions extending upwardly from said support surface, said protrusions to engage protrusions on a wafer.

13. The fixture of claim 12 wherein said fixture includes a shape memory material associated with said protrusions.

14. The fixture of claim 13 wherein said shape memory material is in the form of a sheet having openings formed therein in a regular two dimensional array.

15. The fixture of claim 13 wherein said shape memory material is formed of a woven shape memory material having openings to receive protrusions on said wafer.

16. The fixture of claim 12 wherein said protrusions are formed integrally in said fixture.

17. A method comprising:
engaging a two dimensional array of protrusions on a wafer with a two dimensional array of protrusions on a fixture, the protrusions on the fixture fitting in the gaps between the protrusions on said wafer to enable said wafer to be held by said fixture.

18. The method of claim 17 including forming protrusions on said wafer in the form of bumps.

19. The method of claim 18 including forming protrusions on said wafer in the form of solder bumps.

20. The method of claim 19 including forming a two dimensional array of relatively evenly spaced solder bumps on said wafer.

21. The method of claim 17 including using a releasable adhesive to secure said wafer to said fixture.

22. The method of claim 21 including softening said adhesive to secure said wafer to said fixture and softening said adhesive to remove said wafer from said fixture.

23. The method of claim 17 including using a shape memory material to secure said protrusions on said wafer to said fixture.

24. The method of claim 23 including providing a shape memory material and forming a plurality of openings in said shape memory material.

25. The method of claim 24 including using a material which has an austenitic phase in which the openings are larger than in the martensitic phase.

26. The method of claim 25 including enabling said material to transform to its martensitic phase upon heating.

27. The method of claim 26 including enabling said material to transform to its martensitic phase in response to heating caused by grinding said wafer to thin said wafer.
